(19) United States
(12) Patent Application Publication
(10) Pub. No.: US 2009/0297991 A1
(43) Pub. Date: Dec. 3, 2009

(54) Method for manufacturing lenticular sheet

(75) Inventors: Hideaki Mizutani, Kanagawa-ken (JP); Takayuki Sano, Kanagawa-ken (JP)

Correspondence Address: AKERMAN SENTERFITT, 8100 BOONE BOULEVARD, SUITE 700, VIENNA, VA, 22182-2683, US

(73) Assignee: FUJIFILM Corporation, Tokyo (JP)

(21) Appl. No.: 12/457,101

(22) Filed: Jun. 1, 2009

(30) Foreign Application Priority Data
Jun. 2, 2008 (JP) 2008-144297

(51) Int. Cl. G03F 7/20

(52) U.S. Cl. 430/325

(57) ABSTRACT

According to the method for manufacturing a lenticular sheet of the present invention, the convex arcuate faces are formed not by using a mold but by lithography and heating. Therefore, reduction in quality caused by deterioration of the mold and during demolding can be prevented. Furthermore, since it is not necessary to exchange a mold, productivity can be improved. Moreover, the thickness of the convex arcuate faces can be controlled by controlling the thickness of the coating layer and the resin remaining uncured after light exposure can be removed in the developing step. Therefore, a sheet having thick convex arcuate faces can be manufactured with high productivity.

### BACKGROUND OF THE INVENTION

1. Field of the Invention

The present invention relates to a method for manufacturing a lenticular sheet, and particularly to a method for manufacturing a lenticular sheet having a convex arcuate face pattern formed by ultraviolet irradiation.

2. Description of the Related Art

In electronic displays such as liquid crystal displays and projection screens, a lenticular sheet having a micro concavo-convex pattern formed thereon is used to obtain good images. As a method for manufacturing such a lenticular sheet, various methods are known (see Japanese Patent No. 3309849, Japanese Patent Application Laid-Open Nos. 2002-267805 and 11-142608).

For example, Japanese Patent No. 3309849 discloses a method for forming a stripe-form light-shielding pattern having convex cylindrical lenses, which are formed by a transfer process using a pair of molding rollers and irradiating ultraviolet rays to cure an ultraviolet curing substance. On the other hand, a method for manufacturing a sheet having convex portions such as micro lenses is disclosed in Japanese Patent Application Laid-Open No. 2002-267805, in which lenses (to be formed on the surface thereof) are formed by applying a coating material containing a photosensitive resin, exposing it to light and subjecting it to a heat treatment. That is, a lens film is described. Japanese Patent Application Laid-Open No. 11-142608 discloses a method for forming convex-form micro lenses by spraying a liquid transparent material onto a transparent substrate surface by an inkjet system and fixing/curing the material. Furthermore, Japanese Patent Application Laid-Open No. 9-22995 discloses a method for forming micro lenses by applying a resist, forming a pattern, and thereafter heating it.

### SUMMARY OF THE INVENTION

However, in the method described in Japanese Patent No. 3309849, since convexes are formed by use of a pair of molding rollers (mold), the shape of the mold deteriorates with the progress of manufacturing a lenticular sheet. For this reason, it is difficult to form a high-quality sheet. On the other hand, in the method described in Japanese Patent Application Laid-Open No. 11-142608, since convex shape is formed by the inkjet system, the convex portions having a sufficient thickness cannot be obtained. Therefore, to form thick convex portions, a process of spraying/drying droplets must be repeated a plurality of times, and thus, the productivity of this method is poor. Furthermore, in the method described in Japanese Patent Application Laid-Open No. 11-142608, since convexes are formed by use of a pair of molding rollers (mold), the shape of the mold deteriorates with the progress of manufacturing a lenticular sheet. For this reason, it is difficult to form a high-quality sheet. Furthermore, in the method described in Japanese Patent Application Laid-Open No. 2002-267805, the height of convexes (disclosed herein) is 0.05 to 10 μm. Thus, it is difficult to form thick convexes. Moreover, the method described in Japanese Patent Application Laid-Open No. 9-22995 is a method for manufacturing a micro lens. This method for manufacturing a micro lens is dealt with overcoming a problem: the shape of the micro lens collapses by protruding a square pattern; however, this method is not concerned with the flexibility in the X-Y direction since the shape of the pattern is square.

The present invention has been attained in view of these circumstances. It is an object of the present invention to provide a method for manufacturing a high-quality and defect-free lenticular sheet having thick convexes with good productivity.

The present invention is directed to attaining the aforementioned object. According to a first aspect of the present invention, there is provided a method for manufacturing a lenticular sheet, comprising: a coating step of coating a surface of a sheet with an ultraviolet curing resin solution to form a coating layer; a light exposure step of irradiating the coating layer with ultraviolet rays to cure the coating layer; a developing step of selectively dissolving an uncured region of the coating layer to form a stripe pattern; and a convex arcuate face forming step of forming convex arcuate faces in a width direction of the pattern having a more flexibility than the length direction of the pattern by heating the pattern.

According to the first aspect, the convexes are formed on the sheet not by a conventional transfer process using a mold but by ultraviolet lithography and heating. Therefore, reduction in quality caused by deterioration of the mold can be prevented and a high-quality lenticular sheet can be manufactured.

Furthermore, in the ultraviolet curing, polymerization predominantly proceeds in the length direction rather than the width direction of a mask pattern. Therefore, the flexibility of the width direction and length direction of a stripe pattern can be separately controlled, with the result that a pattern can be accurately formed.

Note that, in the present invention, the term “convex arcuate face” means that a sectional shape of a pattern along the width direction is a semicircle or semi-ellipsoid.

According to a second aspect, there is provided the method according to the first aspect, characterized in that the thickness of the convex arcuate faces is 5 to 150 μm, the thickness of the whole sheet is 40 to 250 μm and a pitch width is 10 to 300 μm.

In the present invention, it is not necessary to exchange a mold. The thickness of the convex arcuate faces can be controlled by controlling the thickness of the coating layer of an ultraviolet curing resin solution. Furthermore, a pattern is formed by removing the ultraviolet curing resin remaining uncured. Therefore, a sheet having thick convex arcuate faces can be manufactured with high productivity.

According to the method for manufacturing a lenticular sheet of the present invention, the convex arcuate faces are formed not by using a mold but by lithography and heating. Therefore, reduction in quality caused by deterioration of the mold and during demolding can be prevented. Furthermore, since it is not necessary to exchange a mold, productivity can be improved. Moreover, the thickness of the convex arcuate faces can be controlled by controlling the thickness of the coating layer and the resin remaining uncured after light exposure can be removed in the developing step. Therefore, a sheet having thick convex arcuate faces can be manufactured with high productivity.

### BRIEF DESCRIPTION OF THE DRAWINGS

FIG. 1 illustrates the steps of the method for manufacturing a lenticular sheet of the present invention; and

FIG. 2 is a perspective view of a lenticular sheet manufactured by the manufacturing method of the present invention.

### DETAILED DESCRIPTION OF THE PREFERRED EMBODIMENTS

Preferred embodiments of the method for manufacturing a lenticular sheet of the present invention will be described with the reference to the accompanying drawings below.

The method for manufacturing a lenticular sheet of the present invention is characterized by having a coating step of coating a surface of a sheet with an ultraviolet curing resin solution to form a coating layer; a light exposure step of irradiating the coating layer with ultraviolet rays to cure the coating layer; a developing step of selectively dissolving an uncured region of the coating layer with a developing solution to form a predetermined pattern; and a convex arcuate face forming step of forming convex arcuate faces by heating the pattern.

### <Coating Step>

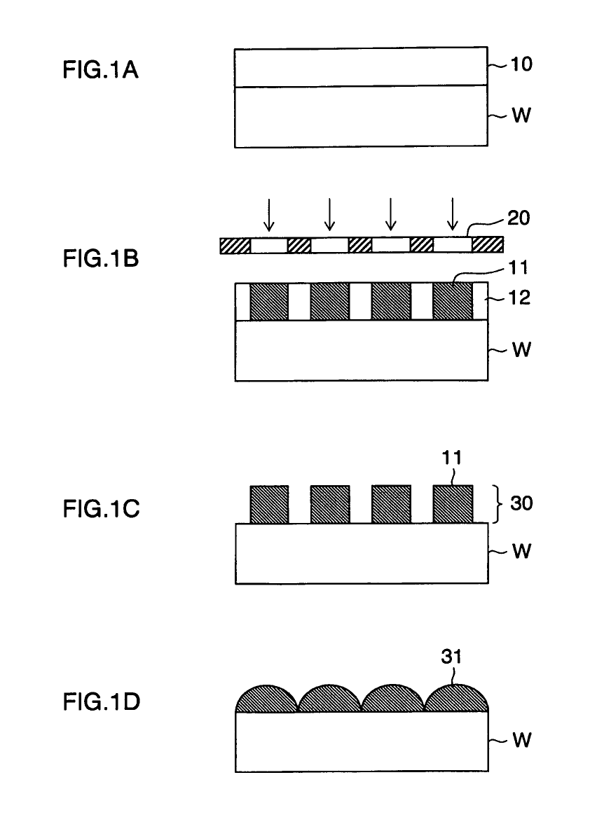

First, the coating step will be described. The coating step is a step of coating a surface of a sheet W with an ultraviolet curing resin solution to form a coating layer 10, as shown in FIG. 1a.

The sheet W to be used in the present invention preferably has a planar configuration. If the substrate does not have planarity (smoothness), a good coating layer cannot be obtained, with the result that it is difficult to form a micro convex shape on the surface. As the sheet W, a resin film, paper (resin coated paper, synthesis paper etc.), a metal foil (aluminum web, etc.) and the like can be used. As a material for the resin film, use may be made of known materials such as polyethylene, polypropylene, polyvinyl chloride, polyvinylidene chloride, polyvinyl acetate, polyester, polyolefin, acryl, polystyrene, polycarbonate, polyamide, PET (polyethylene terephthalate), polyethylene terephthalate produced by biaxial drawing, polyethylene naphthalate, polyamide-imide, polyimide, aromatic polyamide, cellulose acylate, cellulose triacetate, cellulose acetate propionate, cellulose diacetate, and the like. Of them, particularly, polyester, cellulose acylate, acryl, polycarbonate and polyolefin can be preferably used. The thickness of these sheets is preferably 20 to 200 μm, and more preferably 40 to 150 μm.

These sheets may be previously subjected to a treatment such as a corona discharge treatment, a plasma treatment, an adhesion susceptible treatment, a heat treatment and a dust-removal treatment. Alternatively, a sheet to which an underlying layer such as an adhesion layer is previously provided and dried to cure, a sheet having another functional layer previously formed on the rear surface, and the like may be used. Similarly, not only a single-layer sheet but also a laminate sheet having two or more layers may be employed. Furthermore, the sheet is preferably formed of a light transmissible material, such as a transparent material or a semitransparent material.

The method for coating a sheet with an ultraviolet curing resin solution is not particularly limited as long as a uniform thickness can be obtained by coating. A customary method using a spin coater, a slit spin coater, a roll coater, a die coater, a curtain coater or the like can be employed.

The thickness of a coating layer 10 formed on a sheet by coating in the coating step can be appropriately set depending upon the thickness of convex arcuate faces to be formed on the lenticular sheet. The thickness is preferably 10 to 200 μm, and more preferably 20 to 150 μm. In the present invention, convex arcuate faces can be lithographically formed by exposing the coating layer to light and developing it. Therefore, convex arcuate faces, even if they are thick, can be easily formed.

As an ultraviolet curing resin contained in the ultraviolet curing resin solution to be used in forming the coating layer 10, use may be made of a resin containing a compound, which contains a reactive group such as a (meth)acroyl group, a vinyl group and an epoxy group, and a compound, which generates an active species such as a radial and a cation capable of reacting the reactive-group containing compound by irradiation with radioactive rays such as ultraviolet rays.

As the (meth)acroyl group containing compound, a compound having one or two or more (meth)acroyl groups can be used. Furthermore, the reactive group containing compound (monomer) containing an unsaturated group such as an acroyl group or a vinyl group may be used singly or as a mixture of two types or more, if necessary.

As such a (meth)acroyl group containing compound, for example, a monofunctional monomer containing only one (meth)acroyl group containing compound may be mentioned. Examples thereof include isobornyl(meth)acrylate, bornyl(meth)acrylate, tricyclodecanyl(meth)acrylate, dicyclopentanyl(meth)acrylate, dicyclopentenyl(meth)acrylate, cyclohexyl(meth)acrylate, benzyl(meth)acrylate, 4-butylcyclohexyl(meth)acrylate, acryloylmorpholine, 2-hydroxyethyl(meth)acrylate, 2-hydroxypropyl(meth)acrylate, 2-hydroxybutyl(meth)acrylate, methyl(meth)acrylate, ethyl(meth)acrylate, propyl(meth)acrylate, isopropyl(meth)acrylate, butyl(meth)acrylate, amyl(meth)acrylate, isobutyl(meth)acrylate, t-butyl(meth)acrylate, pentyl(meth)acrylate, isoamyl(meth)acrylate, hexyl(meth)acrylate, heptyl(meth)acrylate, octyl(meth)acrylate, isooctyl(meth)acrylate, 2-ethylhexyl(meth)acrylate, nonyl(meth)acrylate, decyl(meth)acrylate, isodecyl(meth)acrylate, undecyl(meth)acrylate, dodecyl(meth)acrylate, lauryl(meth)acrylate, stearyl(meth)acrylate, isostearyl(meth)acrylate, tetrahydrofurfuryl(meth)acrylate, butoxyethyl(meth)acrylate, ethoxydiethylene glycol(meth)acrylate, polyethylene glycol mono(meth)acrylate, polypropylene glycol mono(meth)acrylate, methoxyethylene glycol(meth)acrylate, ethoxyethyl(meth)acrylate, methoxypolyethylene glycol(meth)acrylate and methoxypolypropylene glycol(meth)acrylate.

Furthermore, monofunctional monomers having an aromatic ring may be mentioned. Examples thereof include phenoxyethyl(meth)acrylate, phenoxy-2-methylethyl(meth)acrylate, phenoxyethoxyethyl(meth)acrylate, 3-phenoxy-2-hydroxypropyl(meth)acrylate, 2-phenylphenoxyethyl(meth)acrylate, 4-phenylphenoxyethyl(meth)acrylate, 3-(2-phenylphenyl)-2-hydroxypropyl(meth)acrylate, (meth)acrylate of p-cumyl phenol to which ethylene oxide is reacted, 2-bromophenoxyethyl(meth)acrylate, 4-bromophenoxyethyl(meth)acrylate, 2,4-dibromophenoxyethyl(meth)acrylate, 2,6-dibromophenoxyethyl(meth)acrylate, 2,4,6-tribromophenyl(meth)acrylate, and 2,4,6-tribromophenoxyethyl(meth)acrylate.

Examples of commercially available products of the monofunctional monomers having an aromatic ring include Aronix M113, M110, M101, M102, M5700 and TO-1317 (these set forth above are manufactured by Toagosei Co., Ltd.); Biscoat #192, #193, #220 and 3BM (these set forth above are manufactured by Osaka Organic Chemical Industry Ltd.); NK ester AMP-10G and AMP-20G (these set forth above are manufactured by Shin-Nakamura Chemical Co., Ltd.); Light Acrylate PO-A, P-200A, and epoxy ester M-600A and Light Ester PO (these set forth above are manufactured by Kyoeisha Chemical Co., Ltd.); and New Frontier PHE, CEA, PHE-2, BR-30, BR-31, BR-31M and BR-32 (these set forth above are manufactured by Dai-ichi Kogyo Seiyaku Co., Ltd.).

Furthermore, examples of an unsaturated monomer having two (meth)acryloyl groups in a molecular include alkyldiol diacrylates such as 1,4-butanediol diacrylate, 1,6-hexanediol diacrylate and 1,9-nonanediol diacrylate; polyalkylene glycol diacrylates such as ethylene glycol di(meth)acrylate, tetraethylene glycol diacrylate and tripropylene glycol diacrylate; neopentyl glycol di(meth)acrylate; and tricyclodecane methanol diacrylate.

Examples of an unsaturated monomer having a bisphenol skeleton include ethylene oxide added bisphenol A (meth)acrylate, ethylene oxide added tetrabromo bisphenol A (meth)acrylate, propylene oxide added bisphenol A (meth)acrylate, propylene oxide added tetrabromobisphenol A (meth)acrylate, bisphenol A epoxy(meth)acrylate (obtained by the ring-opening reaction between bisphenol-A diglycidyl ether and (meth)acrylic acid), tetrabromo bisphenol A epoxy(meth)acrylate (obtained by the epoxy ring-opening reaction between tetrabromobisphenol A diglycidyl ether and (meth)acrylic acid), bisphenol F epoxy(meth)acrylate (obtained by the epoxy ring-opening reaction between bisphenol F diglycidyl ether and (meth)acrylic acid), and tetrabromo bisphenol F epoxy(meth)acrylate (obtained by the epoxy ring-opening reaction between tetrabromo bisphenol F diglycidyl ether and (meth)acrylic acid.

Examples of commercially available products of the unsaturated monomer having such a structure include Biscoat #700 and #540 (these set forth above are manufactured by Osaka Organic Chemical Industry Ltd.); Aronix M-208 and M-210 (these set forth above are manufactured by Toagosei Co., Ltd.); NK esters BPE-100, BPE-200, BPE-500 and A-BPE-4 (these set forth above are manufactured by Shin-Nakamura Chemical Co., Ltd.); Light Ester BP-4EA, BP-4PA, epoxy ester 3002M, 3002A, 3000M and 3000A (these set forth above are manufactured by Kyoeisha Chemical Co., Ltd.); KAYARAD R-551 and R-712 (these set forth above are manufactured by Nippon Kayaku Co., Ltd.); BPE-4, BPE-10 and BR-42M (these set forth above are manufactured by Dai-ichi Kogyo Seiyaku Co., Ltd.); Lipoxy VR-77, VR-60, VR-90, SP-1506, SP-1506, SP-1507, SP-1509 and SP-1563 (these set forth above are manufactured by Showa Highpolymer Co., Ltd.); and Neopol V779 and Neopol V779MA (these set forth above are manufactured by U-PICA Company, Ltd.).

Furthermore, examples of a polyfunctional (trifunctional or more) (meth)acrylate unsaturated monomer include (meth)acrylates of a polyhydric alcohol (trivalent or more) such as trimethylolpropane tri(meth)acrylate, pentaerythritol tri(meth)acrylate, trimethylolpropane trioxyethyl(meth)acrylate and tris(2-acryloyloxyethyl)isocyanurate. Examples of commercially available products thereof include Aronix M305, M309, M310, M315, M320, M350, M360 and M408 (these set forth above are manufactured by Toagosei Co., Ltd.); Biscoat #295, #300, #360, GPT, 3PA and #400 (these set forth above are manufactured by Osaka Organic Chemical Industry Ltd.); NK ester TMPT, A-TMPT, A-TMM-3, A-TMM-3L and A-TMMT (these set forth above are manufactured by Shin-Nakamura Chemical Co., Ltd.); Light Acrylate TMP-A, TMP-6EO-3A, PE-3A, PE-4A and DPE-6A (these set forth above are manufactured by Kyoeisha Chemical Co., Ltd.); and KAYARAD PET-30, GPO-303, TMPTA, TPA-320, DPHA, D-310, DPCA-20 and DPCA-60 (these set forth above are manufactured by Nippon Kayaku Co., Ltd.).

Additionally, a urethane(meth)acrylate oligomer may be added. Examples of the urethane(meth)acrylate include polyether polyols such as polyethylene glycol and polytetramethyl glycol; polyester polyols, which are obtained by the reaction between a dibasic acid such as succinic acid, adipic acid, azelaic acid, sebacic acid, phthalic acid, tetrahydrophthalic acid (anhydride), hexahydro phthalic acid (anhydride) and a diol such as ethylene glycol and propylene glycol, diethylene glycol, triethylene glycol, tetraethylene glycol, dipropylene glycol, 1,4-butanediol, 1,6-hexanediol and neopentyl glycol; poly E-caprolactone modified polyol; polymethyl valerolactone modified polyol; alkyl polyols such as ethylene glycol, propylene glycol, 1,4-butanediol, 1,6-hexane diol and neopentyl glycol; bisphenol A skeleton alkylene oxide modified polyols such as ethylene oxide added bisphenol A and propylene oxide added bisphenol A; bisphenol F skeleton alkylene oxide modified polyols such as ethylene oxide added bisphenol F and propylene oxide added bisphenol F; or mixtures thereof; and urethane(meth)acrylate oligomers, which are produced from an organic polyisocyanate such as tolylene diisocyanate, isophorone diisocyanate, hexamethylene diisocyanate, diphenylmethane diisocyanate and xylylene diisocyanate and a hydroxy group containing (meth)acrylate such as 2-hydroxyethyl(meth)acrylate, and 2-hydroxypropyl(meth)acrylate. Urethane(meth)acrylate oligomer is preferable for appropriately maintaining the viscosity of a hardenable composition of the present invention.

Examples of commercially available monomers of these urethane(meth)acrylates include Aronix M120, M-150, M-156, M-215, M-220, M-225, M-240, M-245 and M-270 (these set forth above are manufactured by Toagosei Co., Ltd.); AIB, TBA, LA, LTA, STA, Biscoat #155, IBXA, Biscoat #158, #190, #150, #320, HEA, HPA, Biscoat #2000, #2100, DMA, Biscoat #195, #230, #260, #215, #335HP, #310HP, #310HG and #312 (these set forth above are manufactured by Osaka Organic Chemical Industry Ltd.); Light Acrylate IAA, L-A, S-A, BO-A, EC-A, MTG-A, DMP-A, THF-A, IB-XA, HOA, HOP-A, HOA-MPL, HOA-MPE, Light Acrylate 3EG-A, 4EG-A, 9EG-A, NP-A, 1,6HX-A and DCP-A (these set forth above are manufactured by Kyoeisha Chemical Co., Ltd.); KAYARADTC-110S, HDDA, NPGDA, TPGDA, PEG400DA, MANDA, HX-220 and HX-620 (these set forth above are manufactured by Nippon Kayaku Co., Ltd.); FA-511A, 512A and 513A (these set forth above are manufactured by Hitachi Chemical Co., Ltd.); VP (manufactured by BASF); and ACMO, DMAA and DMAPAA (these set forth above are manufactured by Kohjin Co., Ltd.).

The urethane(meth)acrylate oligomer is obtained as a reaction product of (a) a hydroxy group-containing (meth)acrylate, (b) an organic polyisocyanate and (c) a polyol, and preferably obtained by reacting (a) a hydroxy group containing (meth)acrylate, (b) an organic polyisocyanate, and then reacting with (c) a polyol.

The unsaturated monomers mentioned above may be used singly or as a mixture of a plurality of types, if necessary.

As a photo radical polymerization initiator, mention may be made of acetophenone, acetophenone benzyl ketal, 1-hydroxycyclohexyl phenyl ketone, 2,2-dimethoxy-2-phenyl acetophenone, xanthone, fluorenone, benzaldehyde, fluorene, anthraquinone, triphenylamine, carbazole, 3-methyl acetophenone, 4-chlorobenzophenone, 4,4′-dimethoxybenzophenone, 4,4′-diaminobenzophenone, Michler's Ketone, benzoin propyl ether, benzoin ethyl ether, benzyl dimethyl ketal, 1-(4-isopropylphenyl)-2-hydroxy-2-methylpropan-1-one, 2-hydroxy-2-methyl-1-phenylpropan-1-one, thioxanthone, diethyl thioxanthone, 2-isopropyl thioxanthone, 2-chlorothioxanthone, 2-methyl-1-[4-(methylthio)phenyl]-2-morpholino-propan-1-one, 2,4,6-trimethylbenzoyl diphenylphosphine oxide, bis-(2,6-dimethoxybenzoyl)-2,4,4-trimethylpentylphosphine oxide, ethyl-2,4,6-trimethylbenzoylethoxyphenylphosphine oxide and the like.

Examples of commercially available products of the photo radical polymerization initiator include Irgacure 184, 369, 651, 500, 819, 907, 784, 2959, CGI1700, CGI1750, CGI11850, CG24-61, Darocur 1116 and 1173 (these set forth above are manufactured by Ciba Speciality Chemicals); Lucirin LR8728 and 8893X (these set forth above are manufactured by BASF) and Ubecryl P36 (manufactured by UCB); and KIP150(manufactured by Lamberti). Of them, Lucirin LR8893X is preferred since it is liquid and easily dissolved and has a high sensitivity.

The photo radical polymerization initiator is preferably contained in an ultraviolet curing resin solution in an amount of 0.01 to 10% by weight, and particularly 0.5 to 7% by weight. The upper limit of the content preferably falls within the aforementioned range in view of curing properties of a composition, dynamic properties and optical properties of a cured product, handling and so forth. The lower limit of the content preferably falls within the aforementioned range in view of preventing a decrease of a curing rate.

To the ultraviolet curing resin solution to be used in the present invention, further, a photosensitizer can be added. Examples of the photosensitizer include triethylamine, diethylamine, N-methyldiethanolamine, ethanolamine, 4-dimethylaminobenzoic acid, methyl 4-dimethylaminobenzoate, ethyl 4-dimethyl aminobenzoate and isoamyl 4-dimethylaminobenzoate. Examples of commercially available products thereof include Ubecryl P102, 103, 104 and 105 (these set forth above are manufactured by UCB).

Furthermore, besides the aforementioned components, various additives may be added, if necessary, which include an antioxidant, an ultraviolet absorber, a photostabilizer, a silane coupling agent, a coating surface modifier, a thermal polymerization inhibitor, a leveling agent, a surfactant, a colorant, a storage stabilizer, a plasticizer, a lubricant, a solvent, a filler, an age resister, a wettability modifier and a mold release agent.

Examples of the antioxidant include Irganox 1010, 1035, 1076 and 1222 (these set forth above are manufactured by Ciba Speciality Chemicals); Antigen P, 3C, FR and GA-80 (manufactured by Sumitomo Chemical Co., Ltd.). Example of the ultraviolet absorber include Tinuvin P, 234, 320, 326, 327, 328, 329 and 213 (these set forth above are manufactured by Ciba Speciality Chemicals); Seesorb 102, 103, 110, 501, 202, 712 and 704 (these set forth above are manufactured by Shipro Kaisha, Ltd.). Examples of the photostabilizer include Tinuvin 292, 144 and 622LD (these set forth above are manufactured by Ciba Speciality Chemicals); Sanol LS770 (manufactured by Sankyo); and Sumisorb TM-061 (manufactured by Sumitomo Chemical Co., Ltd.). Examples of the silane coupling agent include γ-aminopropyl triethoxysilane, γ-mercaptopropyl trimethoxysilane and γ-methacryloxypropyl trimethoxysilane. Examples of commercially available products thereof include SH6062 and 6030 (these set forth above are manufactured by Dow Corning Toray, Co., Ltd.); KBE903, 603 and 403 (these set forth above are manufactured by Shin-Etsu Chemical Co., Ltd.). Examples of the coating-surface modifier include a silicone additive such as dimethylsiloxane polyether and a nonionic fluoro surfactant. Examples of commercially available silicon additives include DC-57 and DC-190 (these set forth above are manufactured by Dow Corning Corporation); SH-28PA, SH-29PA, SH-30PA and SH-190 (these set forth above are manufactured by Dow Coming Toray, Co., Ltd.); and KF351, KF352, KF353 and KF354 (these set forth above are manufactured by Shin-Etsu Chemical Co., Ltd.); L-700, L-7002, L-7500, FK-024-90 (these set forth above are manufactured by Nippon Unicar Co. Ltd.). Examples of commercially available nonionic fluoro surfactants include FC-430, FC-171 (these set forth above are manufactured by 3M); and Megaface F-176, F-177, R-08 and F780 (these set forth above are manufactured by DIC Corporation). Examples of the mold release agent include Plysurf A208F (these set forth above are manufactured by Dai-ichi Kogyo Seiyaku Co., Ltd.).

As an organic solvent for controlling the viscosity of the ultraviolet curing resin solution to be used in the present invention, any organic solvent may be used as long as it can be homogeneously mixed with the resin solution without causing precipitation, phase separation or white turbidity. Examples of the organic solvent include acetone, methyl ethyl ketone, methyl isobutyl ketone, ethanol, propanol, butanol, 2-methoxy ethanol, cyclohexanol, cyclohexane, cyclohexanone and toluene. If necessary, they may be used as a mixture of a plurality of types.

### <Dehydration Step>

After completion of the coating step, the coating layer formed on a sheet is dried. The dehydration is performed at a temperature of 40 to 150° C. for 30 to 120 seconds, thereby vaporizing an organic solvent contained in the coating layer. The dehydration is performed, for example, by using a heater or a hot plate or supplying hot air. In the dehydration step, the surface of the coating layer is roughened. Alternatively, if dew condensation water is generated by evaporation heat during the dehydration and deposited to the surface of a composition, the trace of water deposition leads to a planar defect. Therefore, an organic solvent to be contained in the ultraviolet curing resin solution must be selected in consideration of the content, the boiling point and so forth.

### <Light Exposure Step>

Next, the coating layer 10 is irradiated with ultraviolet rays to cure the coating layer (FIG. 1b). The light exposure step is a step of applying light using a photomask 20 formed so as to correspond to the pattern to be formed on the coating layer. Since the coating layer 10 is formed of an ultraviolet curing resin, the portion irradiated with ultraviolet rays is a cured region 11, whereas the portion not irradiated with ultraviolet rays is an uncured region 12.

As a light source to be used in the light-exposure step, a light source having a parallel optical system is preferably used. When the parallel optical system is used, ultraviolet rays can be applied vertically on the photomask; in other words, application of light in another direction can be prevented. As a result, the ultraviolet curing resin having a desired thickness can be accurately hardened. The light source having the parallel optical system is not particularly limited. An aligner and a stepper light exposure apparatus can be used.

### <Developing Step>

The developing step is performed after a predetermined pattern of the coating layer 10 is formed by curing in the light exposure step. This is a step of forming a predetermined pattern 30 by selectively dissolving the uncured region 12 remaining uncured and removing it (FIG. 1c). The method for removing the uncured region 12 is not particularly limited and can be appropriately selected depending upon the purpose. For example, a removal method using a developing solution may be mentioned.

The developing solution is not particularly limited and can be appropriately selected depending upon the purpose. For example, an aqueous alkaline solution and an organic solvent may be mentioned.

The aqueous alkaline solution is not particularly limited. For example, an aqueous alkaline solution containing an alkaline substance (pKa=7 to 13) in a concentration of 0.05 to 5 mol/L is preferred. A diluted aqueous solution of a known alkaline substance as described in Japanese Patent Application Laid-Open No. 5-72724 may be used. Alternatively, the solution to which a small amount of water-miscible organic solvent is added may be used. As the alkaline substance, mention may be made of alkali metal hydroxides (e.g., sodium hydroxide and potassium hydroxide), alkali metal carbonates (e.g., sodium carbonate and potassium carbonate), alkali metal bicarbonates (e.g., sodium hydrogen carbonate and potassium hydrogen carbonate), alkali metal silicates (e.g., sodium silicate and potassium silicate), alkali metal metasilicates (e.g., sodium metasilicate and potassium metasilicate), ammonia, ethylamine, n-propylamine, diethylamine, triethylamine, methyldiethylamine, dimethylethanolamine, triethanolamine, diethanolamine, monoethanolamine, morpholine, tetraalkylammonium hydroxide (e.g., tetramethylammonium hydroxide, tetraethylammonium hydroxide), pyrrole, piperidine, 1,8-diazabicyclo[5,4,0]-7-undecene, 1,5-diazabicyclo[4,3,0]-5-nonane or trisodium phosphate.

Examples of an appropriate water miscible organic solvent as mentioned above include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethyl acetamide, hexamethyl phosphoamide, ethyl lactate, methyl lactate, ε-caprolactam and N-methylpyrrolidone. The concentration of the water-miscible organic solvent is generally 0.1 to 30% by mass.

To the developing solution, a known anionic or nonionic surfactant may be added. The concentration of the surfactant is preferably 0.01 to 10% by mass.

Furthermore, as the organic solvent to be used as a developing solution, for example, alcohols such as methanol and ethanol; ethers such as tetrahydrofuran; glycol ethers such as ethylene glycol monomethyl ether, ethylene glycol dimethyl ether, ethylene glycol methyl ethyl ether and ethylene glycol monoethyl ether; ethylene glycol alkyl ether acetates such as methyl cellosolve acetate and ethyl cellosolve acetate; diethylene glycols such as diethylene glycol monomethyl ether, diethylene glycol diethyl ether, diethylene glycol dimethyl ether, diethylene glycol ethyl methyl ether, diethylene glycol monoethyl ether and diethylene glycol monobutyl ether; propylene glycol alkyl ether acetates such as propylene glycol methyl ether acetate and propylene glycol ethyl ether acetate; aromatic hydrocarbons such as toluene and xylene; ketones such as acetone, methyl ethyl ketone, cyclohexanone and 4-hydroxy-4-methyl-2-pentanone; and esters such as ethyl 2-hydroxy propanoate, methyl 2-hydroxy-2-methyl propionate, ethyl 2-hydroxy-2-methyl propanoate, ethyl ethoxyacetate, ethyl hydroxyacetate, methyl 2-hydroxy-2-methylbutanoate, methyl 3-methoxypropionate, ethyl 3-methoxypropionate, methyl 3-ethoxy propionate, ethyl 3-ethoxypropionate, ethyl acetate, butyl acetate, and lactates (e.g., methyl lactate and ethyl lactate) may be mentioned. Additionally, a high-boiling point solvent can be added including N-methylformamide, N,N-dimethylformamide, N-methylformanilide, N-methylacetamide, N,N-dimethyl acetamide, N-methylpyrrolidone, dimethylsulfoxide, benzylethyl ether, dihexyl ether, acetonyl acetone, isophorone, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate and phenyl cellosolve acetate. These may be used singly or in combination with two or more types.

The temperature of the developing solution can be appropriate selected depending upon the developing properties of the photosensitive layer. For example, a temperature of about 25 to 40° C. is preferred.

The developing method is not particularly limited and can be appropriately selected depending upon the purpose. For example, shower development may be mentioned in which a developing solution is sprayed through a shower nozzle to the coating layer exposed to light to remove the uncured region. Examples of the developing methods other than this may include paddle development, shower development, shower & spin development and dip development. After the development, development residue is preferably removed by spraying a cleaning agent, etc. through a shower nozzle while rubbing it with a brush.

### <Convex Arcuate Face Forming Step>

The convex arcuate face forming step is a step for forming convex arcuate faces 31 by heating the pattern 30 formed in the developing step (FIG. 1d). The heating method is not particularly limited and can be appropriately selected depending upon the purpose. For example, a dry oven, a hot plate, an IR heater or the like may be used. The heating temperature is preferably not less than 80° C. to 250° C. or less, and more preferably not less than 120° C. to 200° C. or less.

Furthermore, in the present invention, a lenticular sheet is manufactured by using a mask pattern in combination with UV cure. With this constitution, convex arcuate faces having flexibility only in the width direction of the stripe pattern can be formed.

### <Cure Treatment Step>

After the convex arcuate face forming step, a cure treatment step is preferably performed in which curing of the convex arcuate faces formed on a sheet is completed. The cure treatment is not particularly limited and can be appropriately selected depending upon the purpose. For example, a whole-surface light exposure treatment and a whole-surface heating treatment can be preferably employed.

As the whole-surface light exposure treatment, mention may be made of a method of irradiating the whole-surface of the convex arcuate faces 31 formed on the sheet W. Because of the whole-surface irradiation, curing of the ultraviolet curing resin forming the convex arcuate faces 31 is accelerated to cure the surface of the convex arcuate faces. The apparatus for use in whole-surface light exposure is not particularly limited and can be appropriately selected depending upon the purpose. For example, a UV exposure apparatus such as an ultra-high pressure mercury lamp may be used.

As the whole-surface heating treatment, a method of heating the whole-surface of the convex arcuate faces 31 formed on the sheet W may be mentioned. Because of the whole-surface hating, the film strength of the surface of the convex arcuate faces 31 can be enhanced.

The heating temperature during the whole-surface heating is preferably 120 to 250° C., and more preferably 120 to 200° C. The heating time is preferably 10 to 120 minutes, and more preferably 15 to 60 minutes.

The apparatus for use in the whole-surface heating is not particularly limited and can be appropriately selected from known apparatuses depending upon the purpose. For example, a dry oven, a hot plate and an IR heater may be mentioned.

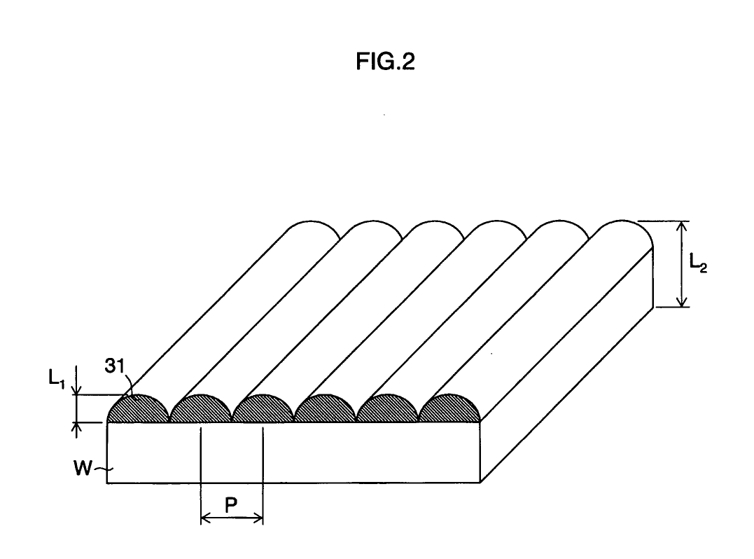

FIG. 2 shows a perspective view of the lenticular sheet manufactured by the manufacturing method of the present invention. As shown in FIG. 2, the lenticular sheet has a stripe pattern having the convex arcuate faces 31. According to the manufacturing method of the present invention, the sheet is manufactured lithographically without using a mold. Therefore, a lenticular sheet (a total thickness (L₂) of 40 to 250 μm) having convex arcuate faces of 5 to 150 μm in thickness (L₁) and 10 to 300 μm in pitch width P can be manufactured without reduction in quality due to deterioration of a mold and failure in demolding.

### EXAMPLES

The present invention will be more specifically described based on examples; however, the present invention is not limited to these examples.

### <Composition of Ultraviolet Curing Resin Solution>

The ultraviolet curing resin solution used herein has the composition shown in Table 1 below.

TABLE 1

| | % by |
|---|---|
| | mass |
| Propylene glycol monomethyl ether acetate (PGMEA) | 35 |
| Methylethyl ketone | 50 |
| Benzyl methacrylate/methacrylic acid (molar ratio = 78/22) random | 5 |
| copolymer | |
| KAYARAD DPHA (manufactured by Nippon Kayaku Co., Ltd.) | 9 |
| Megaface F-176PF (manufactured by DIC Corporation) | 0.05 |
| Irgacure 184 (manufactured by Ciba Speciality Chemicals) | 0.95 |

### <Preparation of Ultraviolet Curing Resin Solution>

The ultraviolet curing resin solution was prepared as follows. A random copolymer of benzyl methacrylate/methacrylic acid (molar ratio=78/22), KAYARAD DPHA, methyl ethyl ketone and propylene glycol monomethyl ether acetate were weighed in accordance with the amounts described in Table 1, mixed at a temperature of 24° C. (±2° C.) and stirred at 150 rpm for 30 minutes. Subsequently, Megaface F-176PF and Irgacure 184 were weighed in accordance with the amounts described in Table 1 and added to the mixture in the order mentioned at a temperature of 25° C. (±2° C.) and stirred at 40° C. (±2° C.) at 150 rpm for 60 minutes. In this way, the ultraviolet curing resin solution was obtained.

### <Formation of Ultraviolet Curing Resin Layer>

A PET film of 100 μm in thickness was coated with the ultraviolet curing resin solution and dried to obtain an ultraviolet curing resin layer of 120 μm in thickness after dry. A mask having an L/S=90/150 μm pattern was set and light was applied by a proximity type light exposure apparatus having an ultra-high pressure mercury lamp (manufactured by Hitachi Electronic Engineering) at a distance of 200 μm between the light exposure mask and the ultraviolet curing resin layer and at a light-exposure amount of 50 mJ/cm².

### <Removal of Uncured Portion>

After the light exposure, a sample was developed in a 1% aqueous triethanol amine solution at 30° C. for 30 seconds and further washed with 0.085 mol/L sodium carbonate, 0.085 mol/L sodium hydrogen carbonate, and a 1% aqueous sodium dibutylnaphthalene sulfonate solution to remove an uncured portion. In this manner, a resist pattern was obtained.

### <Step of Forming Convex Arcuate Face>

The resist pattern was placed in a clean oven (PVHC-331, ESPEC Corp.) and heated at 220° C. for 60 minutes to form convex arcuate faces.

The sample manufactured was cut and the section thereof was observed by a microscope (manufactured by KEYENCE). The thickness (L₁) thereof was 100 μm and the pitch (P) thereof was 240 μm.

What is claimed is:

1. A method for manufacturing a lenticular sheet, comprising:
a coating step of coating a surface of a sheet with an ultraviolet curing resin solution to form a coating layer;
a light exposure step of irradiating the coating layer with ultraviolet rays to cure the coating layer;
a developing step of selectively dissolving an uncured region of the coating layer to form a stripe pattern; and
a convex arcuate face forming step of forming convex arcuate faces in a width direction of the pattern having a more flexibility than the length direction of the pattern by heating the pattern.

2. The method for manufacturing a lenticular sheet according to claim 1, wherein the thickness of the convex arcuate faces is 5 to 150 μm, the thickness of the whole sheet is 40 to 250 μm, and a pitch width is 10 to 300 μm.
